(19) United States
(12) Patent Application Publication
(10) Pub. No.: US 2025/0220982 A1
(43) Pub. Date: Jul. 3, 2025

(54) MONOLITHIC BIDIRECTIONAL JFET SWITCH

(71) Applicant: Wolfspeed, Inc., Durham, NC (US)

(72) Inventors: Rahul R. Potera, Apex, NC (US); Ajith Kanale, Raleigh, NC (US)

(21) Appl. No.: 18/399,226

(22) Filed: Dec. 28, 2023

(51) Int. Cl. H01L 29/808; H01L 27/098; H01L 29/16; H01L 29/78

(52) U.S. Cl. CPC H10D 30/831; H10D 30/668; H10D 62/8325; H10D 84/87

(57) ABSTRACT

A semiconductor device includes a substrate and a drift layer on the substrate, the drift layer having a first conductivity type. The device includes a first plurality of vertical junction field effect (JFET) subcells and a second plurality of vertical JFET subcells on the drift layer. The first plurality of vertical JFET subcells are connected in parallel to form a first JFET device, and the second plurality of vertical JFET subcells are connected in parallel to form a second JFET device. The second JFET device is connected in anti-series with the first JFET device through the drift layer. The device further includes a first gate electrode and a first current terminal in contact with the first plurality of vertical JFET subcells, and a second gate electrode and a second current terminal in contact with the second plurality of vertical JFET subcells.

### FIELD

The present disclosure relates to semiconductor devices and, more particularly, to bidirectional junction field effect transistor (JFET) switching devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), Junction Field Effect Transistors (“JFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Thyristors (“GTO”), MOS-controlled thyristors and various other devices. These power semiconductor devices are generally fabricated from monocrystalline silicon semiconductor material, or, more recently, from silicon carbide or gallium nitride based semiconductor materials.

Power semiconductor devices can have a lateral structure or a vertical structure. In a device having a lateral structure, the terminals of the device (e.g., the drain, gate and source terminals for a power MOSFET device) are on the same major surface (i.e., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more semiconductor layers such as semiconductor substrates and/or semiconductor epitaxial layers. That is, a “semiconductor layer structure” may include a substrate, a substrate including one or more epitaxial layers and/or one or more epitaxial layers that have been removed from a growth substrate.

A conventional silicon carbide power device typically has a silicon carbide substrate, such as a silicon carbide wafer having a first conductivity type (e.g., an n-type substrate), on which an epitaxial layer structure having the first conductivity type (e.g., n-type) is formed. This epitaxial layer structure (which may include one or more separate layers) functions as a drift region of the power semiconductor device. The active region may be formed on and/or in the drift region. The active region acts as a main junction or region for blocking voltage in the reverse bias direction and providing current flow in the forward bias direction. The device may also have an edge termination region adjacent the active region. One or more power semiconductor devices may be formed on the substrate, and each power semiconductor device will typically have its own edge termination. The power semiconductor devices may have a unit cell structure in which the active region of each power semiconductor device includes a large number of individual unit cells that are disposed in parallel to each other and that together function as a single power semiconductor device.

One application for SiC power semiconductor devices is in solid state circuit breakers (SSCBs). SSCBs, which operate at rail voltages of 400V to 800V, are normally on to allow conduction of current. Upon detection of a fault condition, an SSCB is able to quickly turn off to isolate the fault. Consequently, SSCBs are on most of the time and switch to the OFF (non-conductive) state very infrequently. SSCBs therefore need very low conduction loss, while high speed switching controllability is less important. As such SiC JFETs, are well suited for SSCB applications as a lower cost alternative to SiC MOSFETs while still being capable of normally off operation in a cascode arrangement.

FIG. 1 illustrates a bidirectional switch 100 including two cascode switches 104A, 104B in series. Each cascode switch includes a MOSFET 106A, 106B in series with a JFET device 108A, 108B. For example in cascode switch 1 104A, the source of the JFET 108A is connected to the drain of the MOSFET 106A. Likewise, in cascode switch 2 104B, the source of the JFET 108B is connected to the drain of the MOSFET 106B. The sources of the MOSFETs 106A, 106B are connected to the gates of the respective JFETs 108A, 108B to provide a cascode switch. The cascode switches 104A, 104B are connected in series at the drains of the JFETs 108A, 108B. The gates of the MOSFETs 106A, 106B provide control terminals G1, G2 for the bidirectional switch 100, while the sources of the MOSFETs 106A, 106B provide current terminals T1, T2 for the bidirectional switch 100.

FIG. 2 illustrates a bidirectional switching circuit 200 that includes a plurality of bidirectional switches 205. The bidirectional switching circuit 200 includes a first cascode array 204A including a first plurality of cascode switches 202A arranged in parallel and a second cascode array 204B including a second plurality of cascode switches 202B arranged in parallel. Each cascode switch 202A in the first cascode array 204A is connected to a corresponding cascode switch 202B in the second cascode array 204B at the drains of the JFET devices to form a bidirectional cascode switch 205. Thus, the bidirectional switches 205 are connected in parallel.

Power rails 208A, 208B are connected to respective current terminals of each bidirectional cascode switch, and clamping circuits 212A, 212B are provided between the power rails 208A, 208B to provide voltage limitation. Gate drivers 214A, 214B control the bidirectional switching circuit 200 via gate signals based on temperature and voltage (VON) sensing signals from the bidirectional switching circuit 200. The gate drivers 214A, 214B may also provide control signals for open circuit (OC) protection.

### SUMMARY

A semiconductor device according to some embodiments includes a substrate and a drift layer on the substrate, the drift layer having a first conductivity type. The device includes a first plurality of vertical junction field effect (JFET) subcells and a second plurality of vertical JFET subcells on the drift layer. The first plurality of vertical JFET subcells are connected in parallel to form a first JFET device, and the second plurality of vertical JFET subcells are connected in parallel to form a second JFET device. The second JFET device is connected in anti-series with the first JFET device through the drift layer. The device further includes a first gate electrode and a first current terminal in contact with the first plurality of vertical JFET mesas, and a second gate electrode and a second current terminal in contact with the second plurality of vertical JFET mesas. The first and second JFET devices may be vertical JFET devices.

The first plurality vertical JFET subcells may include a plurality of alternating first mesa stripes and first trenches on the drift layer, each of the first mesa stripes comprising sidewall gate regions in opposing sides of the mesa stripe, the sidewall gate regions having a second conductivity type opposite the first conductivity type and defining a channel region in the mesa stripe between the sidewall gate regions, first gate contacts on bottoms of the first trenches adjacent the first mesa stripes, first source contacts on tops of the first mesa stripes, a first gate terminal in electrical contact with the first gate contacts, and a first current terminal in electrical contact with the first source contacts. The second plurality of JFET subcells may include a plurality of alternating second mesa stripes and second trenches on the drift layer, each of the second mesa stripes comprising sidewall gate regions in opposing sides of the mesa stripe, the sidewall gate regions having the second conductivity type and defining a channel region in the mesa stripe between the sidewall gate regions, second gate contacts on bottoms of the second trenches adjacent the second mesa stripes, second source contacts on tops of the second mesa stripes, a second gate terminal in electrical contact with the second gate contacts, and a second current terminal in electrical contact with the second source contacts.

The semiconductor device may further include a reduced surface charge (RESURF) region in the drift layer between the first JFET device and the second JFET device.

The RESURF region may include a plurality of second conductivity regions at a surface of the drift layer between the first JFET device and the second JFET device.

The first gate contacts may not be formed on an outermost trench of the first plurality of trenches adjacent the RESURF region, and the second gate contacts may not be formed on an outermost trench of the second plurality of trenches adjacent the RESURF region.

An outermost mesa stripe of the first plurality of mesa stripes that is adjacent the RESURF region may be narrower than other ones of the first plurality of mesa stripes, and an outermost mesa stripe of the second plurality of mesa stripes that is adjacent the RESURF region may be narrower than other ones of the second plurality of mesa stripes.

The semiconductor device may further include a third plurality of vertical JFET subcells on the drift layer, wherein the third plurality of vertical JFET subcells are connected in parallel with the first plurality of vertical JFET subcells to form the first JFET device, and a fourth plurality of vertical JFET subcells on the drift layer, wherein the fourth plurality of vertical JFET subcells are connected in parallel with the second plurality of vertical JFET subcells to form the second JFET device. The first gate electrode and the first current terminal are in contact with the third plurality of vertical JFET subcells, and the second gate electrode and the second current terminal are in contact with the fourth plurality of vertical JFET subcells.

The semiconductor device may further include reduced surface charge (RESURF) region in the drift layer between the first and second plurality of vertical JFET subcells, between the second and third plurality of vertical JFET subcells, between the third and fourth plurality of vertical JFET subcells.

The semiconductor device may further include a floating terminal on the substrate opposite the drift layer.

The substrate may have the first conductivity type and current between the two JFET devices is also conducted through the substrate In some embodiments, the substrate may have a second conductivity type that is opposite the first conductivity type.

The substrate and the drift layer may include silicon carbide.

The semiconductor device may further include shield regions beneath the trenches, wherein the shield regions have the second conductivity type.

The sidewall gate regions may extend beneath adjacent ones of the trenches, and the shield regions may be beneath the portions of the sidewall gate regions that extend beneath the adjacent ones of the trenches.

A bidirectional switch according to some embodiments may include a semiconductor device as described above, a first field effect transistor having a first drain terminal coupled to the first current terminal in cascode configuration with the first JFET device and a first source terminal coupled to the first gate terminal of the first JFET device, and a second field effect transistor having a second drain terminal coupled to the second current terminal in cascode configuration with the second JFET device and a second source terminal coupled to the second gate terminal of the second JFET device.

A method of forming a semiconductor device according to some embodiments includes forming a drift layer on a substrate, the drift layer having a first conductivity type, forming a first plurality of vertical junction field effect (JFET) subcells on the drift layer, wherein the first plurality of vertical JFET subcells are connected in parallel to form a first JFET device, forming a second plurality of vertical JFET subcells on the drift layer, wherein the second plurality of vertical JFET subcells are connected in parallel to form a second JFET device, wherein the second JFET device is connected in anti-series with the first JFET device through the drift layer, forming a first gate electrode and a first current terminal in contact with the first plurality of vertical JFET mesas, and forming a second gate electrode and a second current terminal in contact with the second plurality of vertical JFET mesas.

A semiconductor device according to some embodiments includes a substrate and a drift layer on the substrate, the drift layer having a first conductivity type. First and second junction field effect transistor (JFET) devices are on the drift layer, wherein the second JFET device is connected in anti-series with the first JFET device through the drift layer. A reduced surface charge (RESURF) region is provided in the drift layer between the first JFET device and the second JFET device.

The RESURF region includes a plurality of second conductivity regions at a surface of the drift layer between the first JFET device and the second JFET device.

The semiconductor device further includes a first plurality of vertical JFET subcells on the drift layer, wherein the first plurality of vertical JFET subcells are connected in parallel to form the first JFET device, and a second plurality of vertical JFET subcells on the drift layer, wherein the second plurality of vertical JFET subcells are connected in parallel to form the second JFET device. A first gate electrode and a first current terminal are in contact with the first plurality of vertical JFET subcells, and a second gate electrode and a second current terminal are in contact with the second plurality of vertical JFET subcells.

The first plurality vertical JFET subcells may include a plurality of alternating first mesa stripes and first trenches on the drift layer, each of the first mesa stripes comprising sidewall gate regions in opposing sides of the mesa stripe, the sidewall gate regions having a second conductivity type opposite the first conductivity type and defining a channel region in the mesa stripe between the sidewall gate regions.

The first plurality vertical JFET subcells further include first gate contacts on bottoms of the first trenches adjacent the first mesa stripes, first source contacts on tops of the first mesa stripes, a first gate terminal in electrical contact with the first gate contacts, and a first current terminal in electrical contact with the first source contacts.

The second plurality of JFET subcells include a plurality of alternating second mesa stripes and second trenches on the drift layer, each of the second mesa stripes comprising sidewall gate regions in opposing sides of the mesa stripe, the sidewall gate regions having the second conductivity type and defining a channel region in the mesa stripe between the sidewall gate regions.

The second plurality of JFET subcells further include second gate contacts on bottoms of the second trenches adjacent the second mesa stripes, second source contacts on tops of the second mesa stripes, a second gate terminal in electrical contact with the second gate contacts, and a second current terminal in electrical contact with the second source contacts.

The first gate contacts may not be formed on an outermost trench of the plurality of first trenches adjacent the RESURF region, and the second gate contacts may not be formed on an outermost trench of the plurality of second trenches adjacent the RESURF region.

An outermost mesa stripe of the first plurality of mesa stripes that is adjacent the RESURF region may be narrower than other ones of the first plurality of mesa stripes, and an outermost mesa stripe of the second plurality of mesa stripes that is adjacent the RESURF region may be narrower than other ones of the second plurality of mesa stripes.

### BRIEF DESCRIPTION OF THE DRAWINGS

FIG. 1 illustrates a conventional bidirectional switch including two cascode switches in series.

FIG. 2 illustrates a conventional bidirectional switching circuit that includes a plurality of bidirectional switches.

FIG. 3 illustrates a bidirectional SiC JFET switch including a monolithically integrated bidirectional JFET device.

FIG. 4 is a cross-sectional illustration of an exemplary structure of a monolithically integrated bidirectional SiC JFET device according to some embodiments.

FIG. 5 is a graph of the specific on-resistance (Rsp) of a monolithically integrated bidirectional JFET device.

FIG. 6 shows a chip layout (in plan view) of a bidirectional JFET including first and second JFET devices.

FIG. 7 shows a chip layout (in plan view) of a bidirectional JFET including metallization layers.

FIGS. 8-12 illustrate bidirectional JFET device structures according to further embodiments.

FIG. 13 illustrates a schematic diagram of a desaturation detection circuit that incorporates a monolithic bidirectional JFET switch according to some embodiments.

### DETAILED DESCRIPTION OF EMBODIMENTS

Embodiments of the inventive concepts will be described more fully hereinafter with reference to the accompanying drawings. The inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout.

Some embodiments described herein provide monolithic bidirectional JFET devices that include integrated anti-series SIC JFETs in one 4-terminal normally-on device. The SiC JFETs can be connected in a cascode arrangement with silicon MOSFETs to form normally off bidirectional switches for SSCB applications. A bidirectional JFET switch as described herein can reduce SiC chip area (and hence cost) for high voltage switching applications compared to other state of the art approaches. Some embodiments may be particularly suitable for applications up to 750V. The achievable reduction in chip area will be lower at higher voltages, but the architectures described herein can also be used for higher voltage ratings, such as 900V, 1200V, etc.

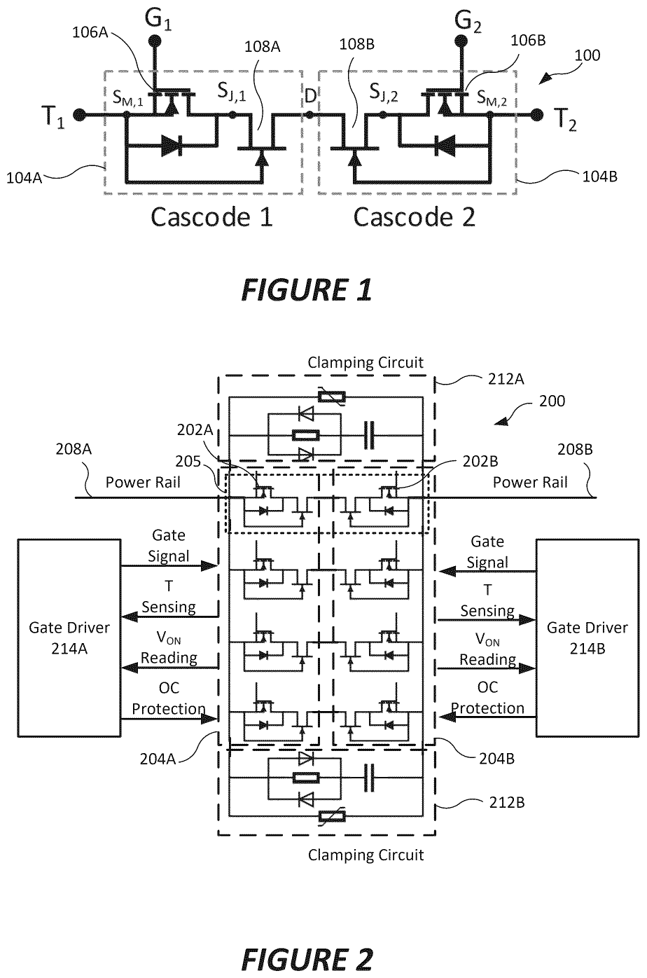

In conventional bidirectional switches such as the arrangement shown in FIG. 1, two separate SiC JFETs are connected anti-series to form a bidirectional switch, because each SiC JFET is capable of blocking voltage in only one direction. There have been proposals to monolithically integrate multiple switches in anti-series on the same chip and furthermore to monolithically integrate lateral SiC JFETs within the same cell on chip. However, in each of those cases, the specific on-resistance of SiC, and hence cost, of providing a monolithically integrated bidirectional switch would have been greater than that of two separate switches connected anti-series.

To address this, some embodiments provide an architecture for a bidirectional SiC JFET that includes two half-cells each including number of JFET sub-cells. The half-cells and sub-cells are arranged in such a way that the specific on-resistance for a 750V rated switch would be reduced when compared to anti-series connected devices. When the specific on-resistance of the device is reduced, the cost for a particular current rating is also reduced. Additionally, reduction in chip area will also reduce capacitance of the switch and enable faster switching.

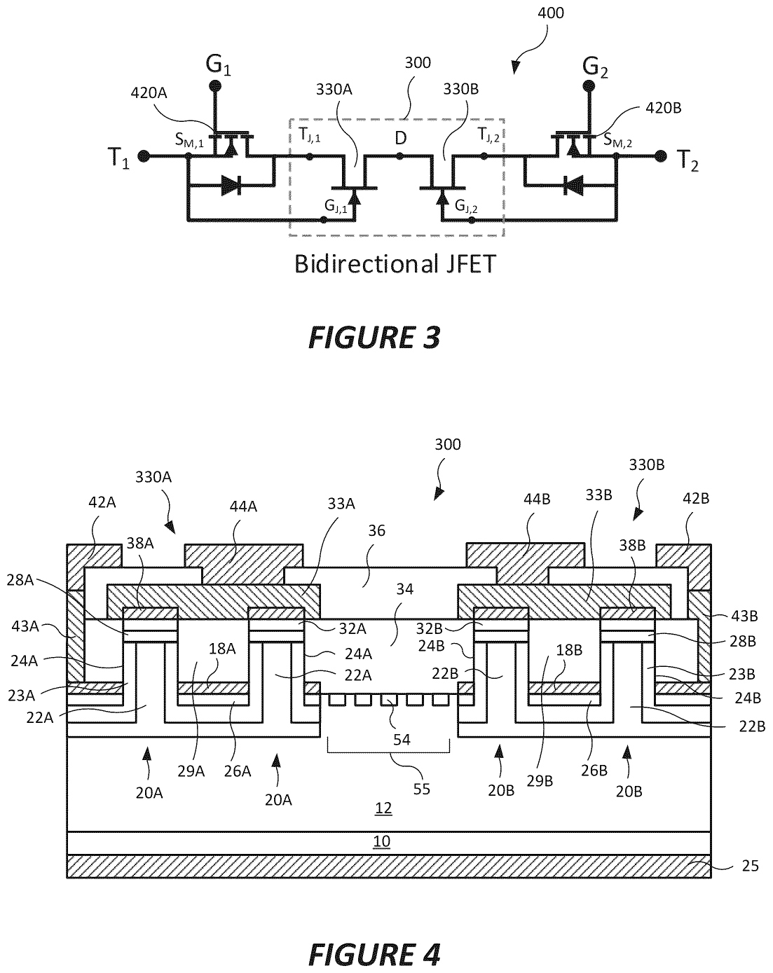

FIG. 3 illustrates a bidirectional SiC JFET switch 400 including a monolithically integrated bidirectional JFET device 300. The monolithically integrated bidirectional JFET device 300 includes two JFET devices 330A, 330B that are provided in respective cascode configurations with MOSFETs 420A, 420B. The bidirectional SiC JFET switch 300 has four terminals, namely TJ,1 and GJ,1 corresponding to the source and gate terminals of the first JFET device 330A and TJ,2 and GJ,2 corresponding to the source and gate terminals of the second JFET device 330B.

FIG. 4 is a cross-sectional illustration of an exemplary structure of a monolithically integrated bidirectional SiC JFET device 300 according to some embodiments. The device 300 generally includes two SiC JFET devices 330A, 330B formed on a common substrate 10. The substrate 10 may be a silicon carbide single crystal having a 4H or 6H polytype. A drift layer 12 is formed on the substrate 10.

Each of the two JFET devices 330A, 330B includes a plurality of JFET subcells 20A, 20B formed as alternating mesa stripes 24A, 24B and trenches 29A, 29B. For example, in the structure shown in FIG. 4, the first JFET device 330A includes two mesa stripes 24A separated by a trench 29A, and the second JFET device 330B includes two mesa stripes 24B separated by a trench 29B. It will be appreciated that each of the JFET devices 330A, 330B may include more mesa stripes 24A, 24B and JFET subcells 20A, 20B than depicted in FIG. 4. The JFET subcells 20A, 20B may be referred to as vertical JFET subcells because current is transported vertically through the mesa stripes from the sources 28A, 28B to the drift layer 12 in the conducting state.

Each JFET subcell 20A, 20B includes respective opposing sidewall gate regions 23A, 23B that define respective channel regions 22A, 22B in the mesa stripes 24A, 24B. Gate contacts 18A, 18B are formed on gate contact regions 26A, 26B at bottom surfaces of the trenches 29A, 29B.

Source regions 28A, 28B and heavily doped source contact regions 32A, 32B are provided at the tops of the mesa stripes 24A, 24B. Source contacts 38A, 38B are formed on the source contact regions 32A, 32B. A first insulating dielectric layer 34 is provided in the trenches 29A, 29B adjacent the mesa stripes 24A, 24B. A first source metallization 33A conductively connects the source contacts 38A of the first JFET device 330A, while a second source metallization 33B conductively connects the source contacts 38B of the second JFET device 330B. A second insulating dielectric layer 36 is formed over the first and second source metallizations 33A, 33B.

A first current terminal 44A is connected to the source contacts 38A of the first JFET device 330A through the source metallization 33A, and a second current terminal 44B is connected to the source contacts 38B of the second JFET device 330B through the source metallization 33B. A first gate terminal 42A is connected to the gate contacts 18A via a gate metallization 43A, and a second gate terminal 42B is connected to the gate contacts 18B via a gate metallization 43B.

A reduced surface charge (RESURF) region 55 is provided at the surface of the drift layer 12 between the two JFET devices 330A, 33B. The RESURF region 55 is provided between the blocking junctions between the gate regions 23A, 23B and the drift layer 12, and includes a plurality of implanted regions that form RESURF rings 54 having a conductivity opposite that of the drift layer 12. The RESURF rings 54 are spaced with n-epi regions in the drift layer 12 between the JFET devices 330A, 330B to block voltage.

The substrate 10 is floating and is isolated from the device terminals 42A, 42B, 44A, 44B. A floating drain contact 25 is provided on the back side of the substrate 10 opposite the drift layer 12.

In some embodiments, the substrate 10, the drift layer 12, the channel regions 22A, 22B, the source regions 28A, 28B and the source contact regions 32A, 32B may have a first conductivity type, and the gate contact regions 26A, 26B and sidewall gate regions 23A, 23B may have a second conductivity that is opposite the first conductivity. For example, the substrate 10, the drift layer 12, the channel regions 22A, 22B, the source regions 28A, 28B and the source contact regions 32A, 32B may be n-type silicon carbide regions, and the gate contact regions 26A, 26B, the sidewall gate regions 23A, 23B and the RESURF rings 54 may be p-type silicon carbide regions.

The substrate 10 may be n+ silicon carbide, and the drift layer 12 may be n-silicon carbide having a doping concentration of about 1.5E16/cm3. The channel regions 22A, 22B may be n-type silicon carbide having a doping concentration of about 5E16/cm3.

The overall width of each of the JFET devices 330A, 330B may be equal to about 2.5 microns multiplied by the number of JFET sub-cells 20A, 20B in the device.

In some embodiments discussed in greater detail below, the substrate 10 may have the second conductivity type (e.g., p-type).

The first and second insulating dielectric layers 34, 36 may include silicon oxide, silicon nitride, silicon oxynitride, etc.

During on-state operation, current flows between the current terminals 44A, 44B through the channel regions 22A, 22B and the drift layer 12. During off-state operation, the channel regions 22A, 22B are pinched off by a depletion region formed at the junction between the sidewall gate regions 23A, 23B and the respective channel regions 22A, 22B.

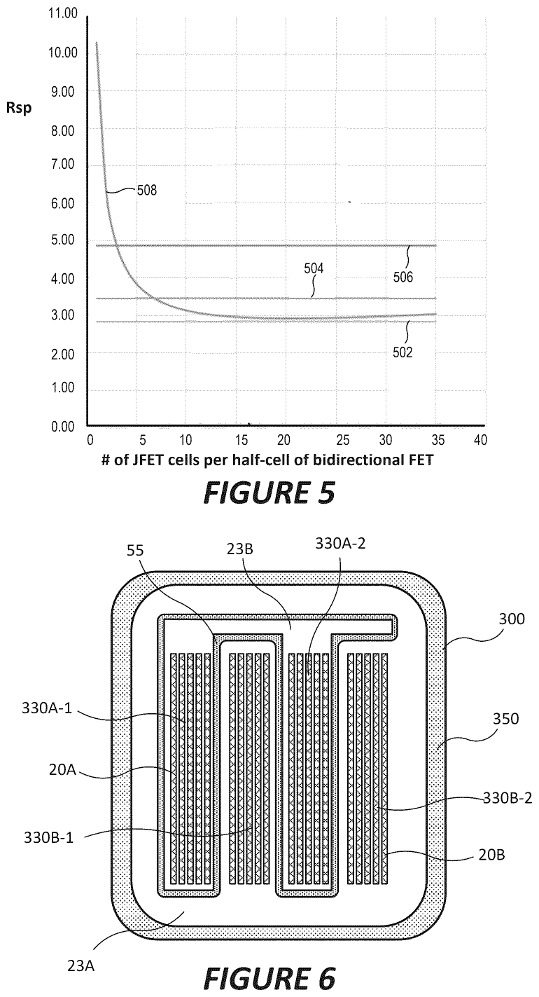

FIG. 5 is a graph of the specific on-resistance (Rsp) of a monolithically integrated bidirectional JFET device as shown in FIG. 4, as a function of the number of JFET subcells 20A, 20B within each JFET device 330A, 330B of a device 300 that has a 750 V blocking voltage rating. The specific on-resistance of the device 300, shown in curve 508, decreases with the number of JFET cells per device 330A, 330B until it reaches a minimum at about 20 cells, and then increases. For higher rated voltages, the specific on-resistance will be higher and the minimum will happen at a higher number of cells.

Also shown in FIG. 5 are the specific on-resistances of 750V bidirectional FETs formed by connecting separate anti-series JFETs with different substrate thicknesses, namely 100 microns (curve 502), 180 microns (curve 504) and 360 microns (curve 506). The substrate thickness is important for a separate anti-series connection, because in that case current flows vertically through the entire substrate, while in a bidirectional lateral JFET device 300, the current only flows laterally through the substrate 10 for short distances. If the substrate is of full thickness (no thinning), then the monolithic bidirectional FET has a significant advantage in terms of specific on-resistance. However, as can be seen in FIG. 5, that advantage reduces as the substrate is thinned, and vanishes when the substrate is thinned to 100 μm. From FIG. 5, it can be concluded that at 750V, the advantage in chip area reduction for the monolithic bidirectional FET is coupled with the opportunity cost of substrate thinning that can be avoided and cycle time that can be gained.

FIG. 6 shows a chip layout (in plan view) of a bidirectional JFET 300 including first and second JFET devices 330A, 330B. The first JFET device 330A is divided into first and second sub-devices 330A-1, 330A-2, each of which includes a plurality of subcells 20A, and the second JFET device 330B is divided into first and second sub-devices 330B-1, 330B-2, each of which includes a plurality of subcells 20B. The sub-devices 330A-1, 330A-2, 330B-1, 330B-2 alternate across the surface of the device 300, and are separated by a RESURF region 55. The gate region 23A of the first JFET device 330A is provided within the RESURF region 55, while the gate region 23B of the second JFET device 330B is provided outside the RESURF region 55. An edge termination region 350 surrounds the first and second JFET devices 330A, 330B.

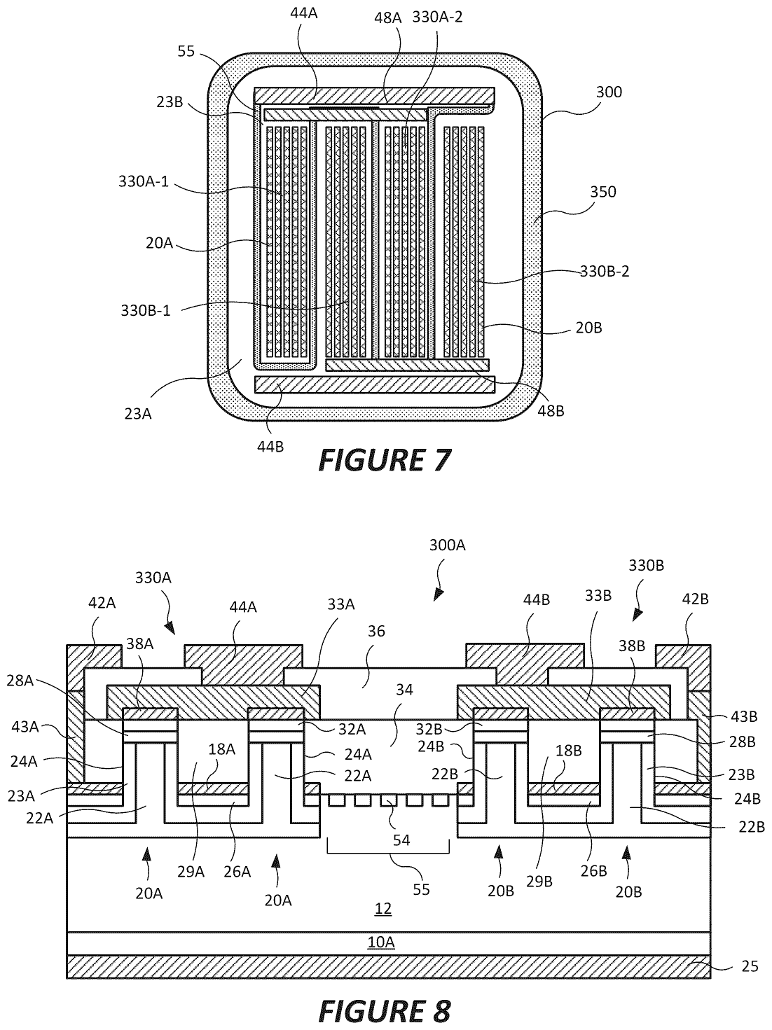

FIG. 7 shows a chip layout (in plan view) of the bidirectional JFET 300 including metallization layers. In particular, a gate bus 44A and terminal bus 48A are provided to connect to the gate and terminal contacts of the first JFET device 330A, respectively, and a gate bus 44B and terminal bus 48B are provided to connect to the gate and terminal contacts of the second JFET device 330B. Additional metal layers may be provided.

FIG. 8 illustrates a bidirectional JFET device structure 300A according to further embodiments. The bidirectional JFET device structure 300A is similar to the bidirectional JFET device structure 300 shown in FIG. 4, except that the substrate 10A of the bidirectional JFET device structure 300A is the opposite conductivity of the drift layer 12 (e.g., p-type). The substrate 10A may have a high doping concentration (e.g., p+).

When a p+ substrate is provided, the n-drift layer 12 can be depleted in blocking state by both the p-type RESURF region 55 and by the p+ substrate. This may allow better voltage control in the reversed blocking state, and hence allow reduction of the width of the RESURF region, which can reduce the specific on-resistance, reduce chip area and/or reduce manufacturing costs.

However, the use of a p+ substrate 10A may also eliminate the current path through substrate 10A in the on-state, which may increase the specific on-resistance and/or increase chip area when multiple JFET subcells 20A, 20B are used.

Accordingly, when a p+ substrate 10A is used, there may be a lower optimum number of subcells per device compared to the device 300 shown in FIG. 4.

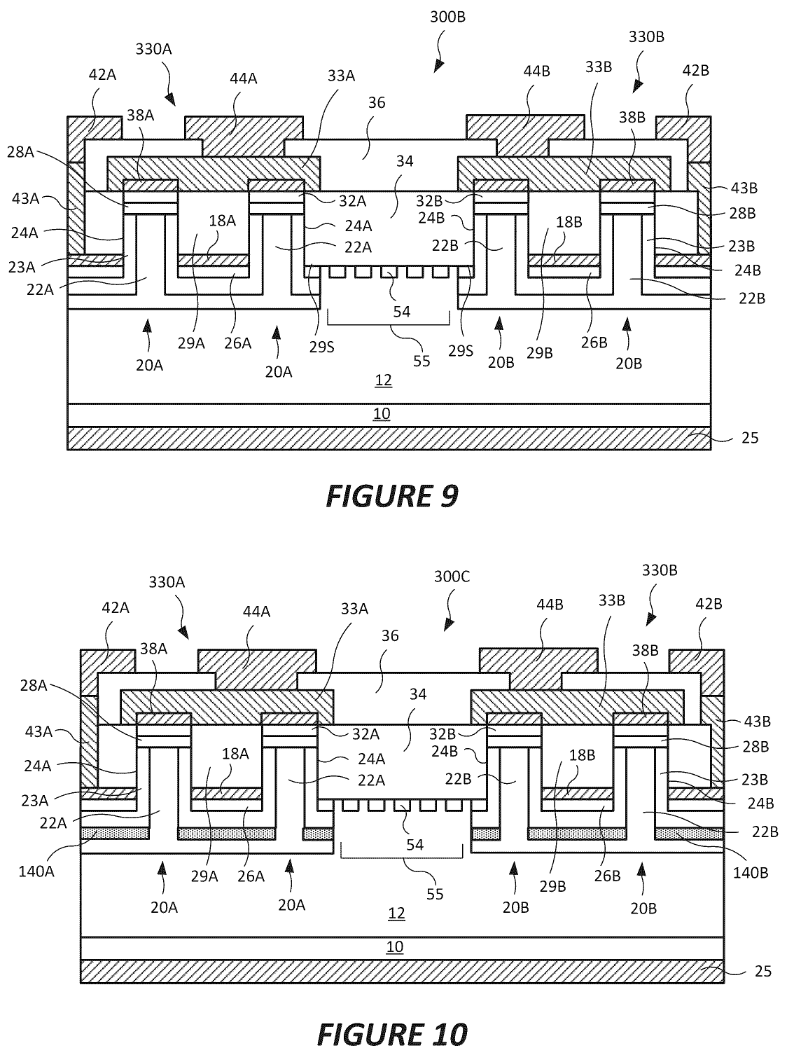

FIG. 9 illustrates a bidirectional JFET device structure 300B according to further embodiments. The bidirectional JFET device structure 300B is similar to the bidirectional JFET device structure 300 shown in FIG. 4, except that in the bidirectional JFET device structure 300B, the gate contacts 18A are not formed on bottom surfaces of the trenches 29A, 29B adjacent the RESURF region 55.

In the embodiment shown in FIG. 9, the gate contact 18A, 18B is not routed on the side of the last mesa stripe 24A,24B next to the RESURF region 55 separating the devices 330A, 330B. This allows reduction of cell pitch by reducing space that would have to be dedicated to having the gate contacts in this region. There is a trade-off however, in that for the mesa stripes 24A, 24B at ends of the arrays, the gate signal will experience more delay for the gate on the side of the RESURF region 55 (since without contact metallization there will locally be more gate resistance there) and the transconductance will be reduced for these last mesa stripes 24A, 24B. To address this trade-off, the last mesa stripes 24A, 24B may be laid out narrower, which will increase the threshold voltage locally for those mesa stripes 24A, 24B, thereby requiring less voltage to turn them off. The on-resistance of last mesa stripes 24A, 24B will thereby increase marginally, but this might be acceptable if the reduction in cell pitch is significant.

FIG. 10 illustrates a bidirectional JFET device structure 300C according to further embodiments. The bidirectional JFET device structure 300B is similar to the bidirectional JFET device structure 300 shown in FIG. 4, except that the bidirectional JFET device structure 300C includes heavily doped second conductivity type (e.g., p+) shield regions 140A beneath portions of the sidewall gate regions 23A, 23B that extend beneath the trenches 29A, 29B. The p+ shield regions 140A, 140B may help to protect the gate junction between the sidewall gate regions 23A, 23B and the channel regions 22A, 22B from high electric fields.

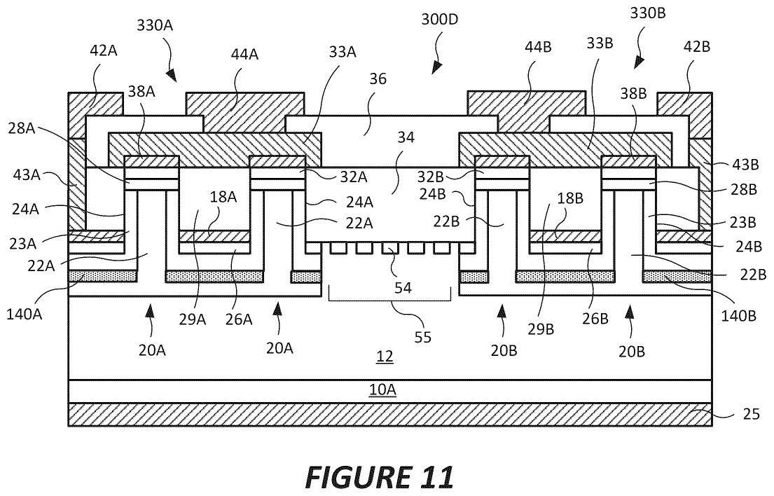

FIG. 11 illustrates a bidirectional JFET device structure 300D according to further embodiments. The bidirectional JFET device structure 300D is similar to the bidirectional JFET device structure 300A shown in FIG. 8 including a second conductivity type substrate 10A, except that the bidirectional JFET device structure 300D includes heavily doped second conductivity type (e.g., p+) shield regions 140A beneath portions of the sidewall gate regions 23A, 23B that extend beneath the trenches 29A, 29B.

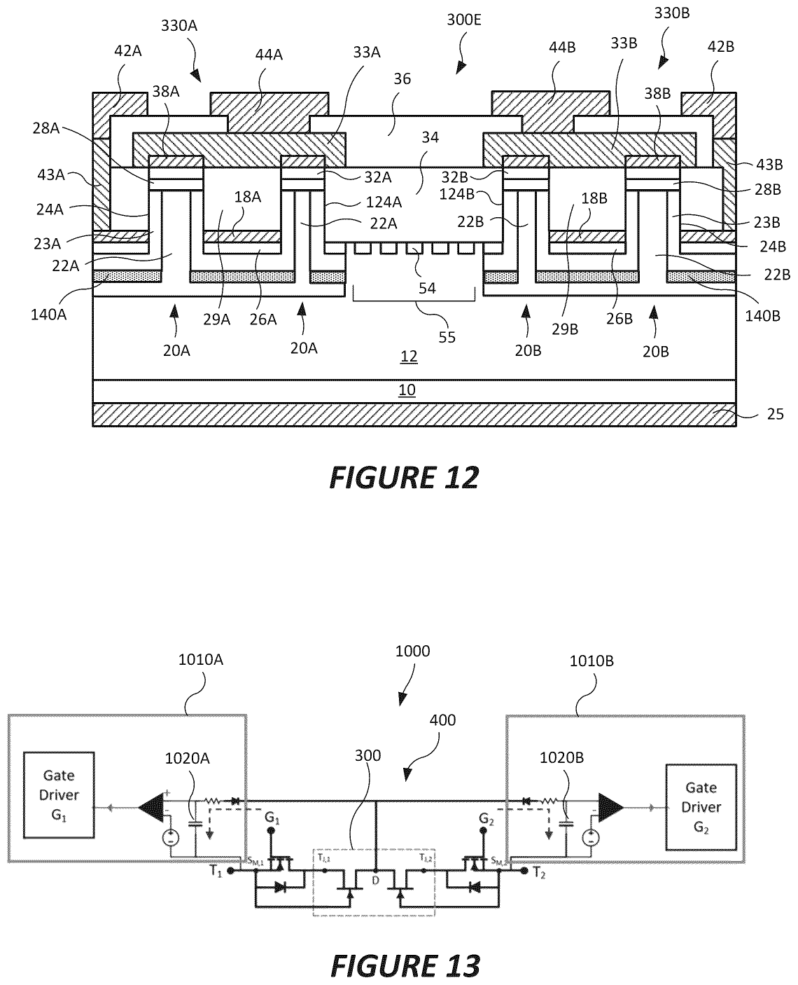

FIG. 12 illustrates a bidirectional JFET device structure 300E according to further embodiments. The bidirectional JFET device structure 300E includes heavily doped second conductivity type (e.g., p+) shield regions 140A beneath portions of the sidewall gate regions 23A, 23B that extend beneath the trenches 29A, 29B. In addition, in the bidirectional JFET device structure 300E, the outermost mesa stripes 124A, 124B that are closest to the RESURF region 55 are narrower than the inner mesa stripes 24A, 24B that are not adjacent to the RESURF region 55. The outermost mesa stripes 124A, 124B may be about 0.1-0.2 μm narrower than other mesa stripes. Such narrower mesas may locally increase the threshold voltage to compensate for lack of a silicided gate next to the RESURF region 55.

Reducing the mesa width may also help to reduce cell pitch, which may allow more cells to be placed in a given chip size. The absence of a gate contact on the outside of the outermost mesa stripes 124A, 124B allows creation the mesa stripe without needing a metal finger. This may improve current density in the chip.

The exact mesa width may be as low as physically possible in the manufacturing setup. Reducing the mesa width comes with tradeoff however. For example, the absence of a gate finger means that the gate voltage reaches that locality with a slight delay (e.g., nanoseconds), which increases the resistance of that locality and reduces the transconductance of that locality (i.e., the speed with which the JFET can turn on if the gate voltage signal is increased from an off-state value to an on-state value).

An advantage of narrowing the outermost mesa stripes 124A, 124B is that it increases the local threshold voltage of the mesa stripes (JFETs have a negative threshold voltage). This increase means that the locality will have a less negative voltage, e.g., 3 volts instead of −9 volts, meaning that the locality with a narrow mesas need to go from 0 to −3 V to turn off as opposed to 0 to −9 V for the rest of the chip. The nanoseconds lost due to gate voltage delay is made up by shorter voltage traversals during turn-off.

It will be appreciated that the narrow mesa modification as shown in FIG. 12 can be applied to all the of the embodiments described herein, including the structures shown in FIGS. 4 and 8-11.

FIG. 13 illustrates a schematic diagram of a desaturation detection circuit 1000 that may incorporate a monolithic bidirectional JFET switch 400 according to some embodiments. Desaturation circuits use the voltage drop across a switch to charge a capacitor 1020A, 1020B. When the voltage drop across the capacitor 1020A, 1020B exceeds a predefined ‘fault condition voltage’ level shown by the DC voltage supply, a signal is sent to the gate driver G1, G2, which turns off the gate drive signal.

Rather than floating, the drain terminal 25 in the bidirectional JFET switch 300 can be drawn out as an external pin for this purpose.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concepts belong. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “horizontal,” “lateral,” “vertical,” “beneath,” “over,” “on,” etc., may be used herein to describe a relationship of one element, layer or region to another element, layer or region as illustrated in the figures. It will be understood that these terms are intended to encompass different orientations of the device in addition to the orientation depicted in the figures.

Embodiments of the inventive concepts are described herein with reference to cross-section illustrations that are schematic illustrations of idealized embodiments (and intermediate structures) of the inventive concepts. The thickness of layers and regions in the drawings may be exaggerated for clarity. Additionally, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concepts.

Some embodiments of the inventive concepts are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

It also will be understood that, as used herein, the terms “row” and “column” indicate two non-parallel directions that may be orthogonal to one another. However, the terms row and column do not indicate a particular horizontal or vertical orientation.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a substrate;
a drift layer on the substrate, the drift layer having a first conductivity type;
a first plurality of vertical junction field effect (JFET) subcells on the drift layer, wherein the first plurality of vertical JFET subcells are connected in parallel to form a first JFET device;
a second plurality of vertical JFET subcells on the drift layer, wherein the second plurality of vertical JFET subcells are connected in parallel to form a second JFET device, wherein the second JFET device is connected in anti-series with the first JFET device through the drift layer;
a first gate electrode and a first current terminal in contact with the first plurality of vertical JFET subcells; and
a second gate electrode and a second current terminal in contact with the second plurality of vertical JFET subcells.

2. The semiconductor device of claim 1, wherein the first plurality vertical JFET subcells comprise:
a plurality of alternating first mesa stripes and first trenches on the drift layer, each of the first mesa stripes comprising sidewall gate regions in opposing sides of the mesa stripe, the sidewall gate regions having a second conductivity type opposite the first conductivity type and defining a channel region in the mesa stripe between the sidewall gate regions;
first gate contacts on bottoms of the first trenches adjacent the first mesa stripes;
first source contacts on tops of the first mesa stripes;
a first gate terminal in electrical contact with the first gate contacts; and
a first current terminal in electrical contact with the first source contacts; and
wherein the second plurality of JFET subcells comprise:
a plurality of alternating second mesa stripes and second trenches on the drift layer, each of the second mesa stripes comprising sidewall gate regions in opposing sides of the mesa stripe, the sidewall gate regions having the second conductivity type and defining a channel region in the mesa stripe between the sidewall gate regions;
second gate contacts on bottoms of the second trenches adjacent the second mesa stripes;
second source contacts on tops of the second mesa stripes;
a second gate terminal in electrical contact with the second gate contacts; and
a second current terminal in electrical contact with the second source contacts.

3. The semiconductor device of claim 2, further comprising:
a reduced surface charge (RESURF) region in the drift layer between the first JFET device and the second JFET device.

4. The semiconductor device of claim 3, wherein the RESURF region comprises a plurality of second conductivity regions at a surface of the drift layer between the first JFET device and the second JFET device.

5. The semiconductor device of claim 3, wherein the first gate contacts are not formed on an outermost trench of the plurality of first trenches adjacent the RESURF region, and the second gate contacts are not formed on an outermost trench of the plurality of second trenches adjacent the RESURF region.

6. The semiconductor device of claim 3, an outermost mesa stripe of the first plurality of mesa stripes that is adjacent the RESURF region is narrower than other ones of the first plurality of mesa stripes, and an outermost mesa stripe of the second plurality of mesa stripes that is adjacent the RESURF region is narrower than other ones of the second plurality of mesa stripes.

7. The semiconductor device of claim 1, further comprising:
a third plurality of vertical JFET subcells on the drift layer, wherein the third plurality of vertical JFET subcells are connected in parallel with the first plurality of vertical JFET subcells to form the first JFET device;
a fourth plurality of vertical JFET subcells on the drift layer, wherein the fourth plurality of vertical JFET subcells are connected in parallel with the second plurality of vertical JFET subcells to form the second JFET device;
wherein the first gate electrode and the first current terminal are in contact with the third plurality of vertical JFET subcells, and the second gate electrode and the second current terminal are in contact with the fourth plurality of vertical JFET subcells.

8. The semiconductor device of claim 7, further comprising: a reduced surface charge (RESURF) region in the drift layer between the first and second plurality of vertical JFET subcells, between the second and third plurality of vertical JFET subcells, between the third and fourth plurality of vertical JFET subcells.

9. The semiconductor device of claim 1, further comprising a floating terminal on the substrate opposite the drift layer.

10. The semiconductor device of claim 1, wherein the substrate has the first conductivity type and wherein current between the first and second JFET devices is also conducted through the substrate.

11. The semiconductor device of claim 1, wherein the substrate has a second conductivity type that is opposite the first conductivity type.

12. The semiconductor device of claim 1, wherein the substrate and the drift layer comprise silicon carbide.

13. The semiconductor device of claim 2, further comprising shield regions beneath the trenches, wherein the shield regions have the second conductivity type.

14. The semiconductor device of claim 13, wherein the sidewall gate regions extend beneath adjacent ones of the trenches, and wherein the shield regions are beneath portions of the sidewall gate regions that extend beneath the adjacent ones of the trenches.

15. A bidirectional switch, comprising:
a semiconductor device according to claim 1;
a first field effect transistor having a first drain terminal coupled to the first current terminal in cascode configuration with the first JFET device and a first source terminal coupled to the first gate terminal of the first JFET device; and
a second field effect transistor having a second drain terminal coupled to the second current terminal in cascode configuration with the second JFET device and a second source terminal coupled to the second gate terminal of the second JFET device.

16. A method of forming a semiconductor device, comprising:
forming a drift layer on a substrate, the drift layer having a first conductivity type;
forming a first plurality of vertical junction field effect (JFET) subcells on the drift layer, wherein the first plurality of vertical JFET subcells are connected in parallel to form a first JFET device;
forming a second plurality of vertical JFET subcells on the drift layer, wherein the second plurality of vertical JFET subcells are connected in parallel to form a second JFET device, wherein the second JFET device is connected in anti-series with the first JFET device through the drift layer;
forming a first gate electrode and a first current terminal in contact with the first plurality of vertical JFET subcells; and
forming a second gate electrode and a second current terminal in contact with the second plurality of vertical JFET subcells.

17. The method of claim 16, wherein the first plurality vertical JFET subcells comprise:
a plurality of alternating first mesa stripes and first trenches on the drift layer, each of the first mesa stripes comprising sidewall gate regions in opposing sides of the mesa stripe, the sidewall gate regions having a second conductivity type opposite the first conductivity type and defining a channel region in the mesa stripe between the sidewall gate regions;
first gate contacts on bottoms of the first trenches adjacent the first mesa stripes;
first source contacts on tops of the first mesa stripes;
a first gate terminal in electrical contact with the first gate contacts; and
a first current terminal in electrical contact with the first source contacts; and
wherein the second plurality of JFET subcells comprise:
a plurality of alternating second mesa stripes and second trenches on the drift layer, each of the second mesa stripes comprising sidewall gate regions in opposing sides of the mesa stripe, the sidewall gate regions having the second conductivity type and defining a channel region in the mesa stripe between the sidewall gate regions;
second gate contacts on bottoms of the second trenches adjacent the second mesa stripes;
second source contacts on tops of the second mesa stripes;
a second gate terminal in electrical contact with the second gate contacts; and
a second current terminal in electrical contact with the second source contacts.

18. The method of claim 17, further comprising:
forming a reduced surface charge (RESURF) region in the drift layer between the first JFET device and the second JFET device.

19. A semiconductor device, comprising:
a substrate;
a drift layer on the substrate, the drift layer having a first conductivity type;
a first junction field effect transistor (JFET) device on the drift layer;
a second JFET device on the drift layer, wherein the second JFET device is connected in anti-series with the first JFET device through the drift layer; and
a reduced surface charge (RESURF) region in the drift layer between the first JFET device and the second JFET device.

20. The semiconductor device of claim 19, wherein the RESURF region comprises a plurality of second conductivity regions at a surface of the drift layer between the first JFET device and the second JFET device.

21. The semiconductor device of claim 19, further comprising:
a first plurality of vertical JFET subcells on the drift layer, wherein the first plurality of vertical JFET subcells are connected in parallel to form the first JFET device;
a second plurality of vertical JFET subcells on the drift layer, wherein the second plurality of vertical JFET subcells are connected in parallel to form the second JFET device; and
a first gate electrode and a first current terminal in contact with the first plurality of vertical JFET subcells; and
a second gate electrode and a second current terminal in contact with the second plurality of vertical JFET subcells.

22. The semiconductor device of claim 21, wherein the first plurality vertical JFET subcells comprise:
a plurality of alternating first mesa stripes and first trenches on the drift layer, each of the first mesa stripes comprising sidewall gate regions in opposing sides of the mesa stripe, the sidewall gate regions having a second conductivity type opposite the first conductivity type and defining a channel region in the mesa stripe between the sidewall gate regions;
first gate contacts on bottoms of the first trenches adjacent the first mesa stripes;
first source contacts on tops of the first mesa stripes;
a first gate terminal in electrical contact with the first gate contacts; and
a first current terminal in electrical contact with the first source contacts; and
wherein the second plurality of JFET subcells comprise:
a plurality of alternating second mesa stripes and second trenches on the drift layer, each of the second mesa stripes comprising sidewall gate regions in opposing sides of the mesa stripe, the sidewall gate regions having the second conductivity type and defining a channel region in the mesa stripe between the sidewall gate regions;
second gate contacts on bottoms of the second trenches adjacent the second mesa stripes;
second source contacts on tops of the second mesa stripes;
a second gate terminal in electrical contact with the second gate contacts; and
a second current terminal in electrical contact with the second source contacts.

23. The semiconductor device of claim 22, wherein the first gate contacts are not formed on an outermost trench of the plurality of first trenches adjacent the RESURF region, and the second gate contacts are not formed on an outermost trench of the plurality of second trenches adjacent the RESURF region.

24. The semiconductor device of claim 22, wherein an outermost mesa stripe of the first plurality of mesa stripes that is adjacent the RESURF region is narrower than other ones of the first plurality of mesa stripes, and an outermost mesa stripe of the second plurality of mesa stripes that is adjacent the RESURF region is narrower than other ones of the second plurality of mesa stripes.
